(19) United States
(12) Patent Application Publication
(10) Pub. No.: US 2022/0123559 A1
(43) Pub. Date: Apr. 21, 2022

(54) System For Detecting, Assessing, and Displaying Battery Faults

(71) Applicant: The Regents of The University of Michigan, Ann Arbor, MI (US)

(72) Inventors: Anna G. Stefanopoulou, Ann Arbor, MI (US); Jason B. Siegel, Ann Arbor, MI (US); Ting Cai, Ann Arbor, MI (US)

(21) Appl. No.: 17/503,478

(22) Filed: Oct. 18, 2021

Related U.S. Application Data
(60) Provisional application No. 63/092,959, filed on Oct. 16, 2020.

(51) Int. Cl. H02J 7/00; G01R 31/371; G09B 5/02; G06F 3/14; G06K 7/14

(52) U.S. Cl. CPC H02J 7/005; H02J 7/0029; H02J 7/007; G06K 7/1417; G01R 31/371; G09B 5/02; G06F 3/14; H02J 7/00032

(57) ABSTRACT

Disclosed is a system and method for detecting, assessing, and displaying a battery fault, such as an internal short circuit in a battery cell. The system includes a battery; a sensor for outputting a sensor signal correlating to a measurement of a chemical, electrical, or physical property of the battery; and a controller in electrical communication with the sensor and a display device. The controller is configured to execute a program stored in the controller to: (i) detect and assess a fault in the battery based on the sensor signal, and (ii) transmit a display signal to the display device such that the display device produces an image indicative of the presence or the absence of a fault in the battery. The display device can be a virtual reality headset to be used for first responders and other beneficiaries for an electric vehicle fire.

### CROSS-REFERENCES TO RELATED APPLICATIONS

This application claims priority to U.S. Patent Application No. 63/092,959 filed Oct. 16, 2020, which is hereby incorporated by reference in its entirety.

### STATEMENT REGARDING FEDERALLY SPONSORED RESEARCH

Not Applicable.

### BACKGROUND OF THE INVENTION

### 1. Field of the Invention

This invention relates to a system and a method for detecting and assessing a battery fault, such as an internal short circuit in a battery cell, and displaying the information to operators and first responders.

### 2. Description of the Related Art

Vehicles are used to facilitate modern transportation. Electric vehicles, also referred to as all-electric vehicles, include a battery system and utilize electric power for the entirety of their motive power. A plug in power source is needed for electric vehicles for charging. Hybrid vehicles and plug-in hybrid electric vehicles include both an internal combustion engine and a battery system. The battery is capable of being charged from a plug-in power source. Additionally, the internal combustion engine can turn a generator, that supplies a current to an electric motor to move the vehicle.

Large lithium ion batteries are commonly used in all-electric vehicles and hybrid electric vehicles. Lithium ion batteries are significantly reactive and need electronic battery management systems to keep the battery within a safe operating window of voltage, temperature and stress. Lithium ion batteries display familiar electric, thermal, and mechanical characteristics when they operate under safe nominal conditions. As the cells, modules and packs are used and aged these characteristics change and there are many techniques for estimating the state of health of the battery

In lithium ion batteries, the growth in energy density increases the risk and severity of failures due to internal or external short-circuiting necessitating more stringent safety requirements. Thermal runaway of lithium ion batteries is a critical safety issue. Lithium ion batteries employ a separator between the anode and the cathode to electrically separate the anode and the cathode from one another while allowing lithium ions to pass through. When the battery passes electrons through an external circuit, the permeability of the separator to lithium ions enables the battery to close the circuit. Short circuiting the separator by providing a conductive path across it allows the battery to discharge rapidly. A short circuit across the separator can result from improper charging and discharging, or cell manufacturing defects. More particularly, improper charging can lead to the deposition of metallic lithium dendrites on the surface of the anode and these dendrites grow to penetrate the separator so as to provide a conductive path for electrons from the anode to the cathode. The lower resistance of these conductive paths allows for rapid discharge and the generation of significant joule heat. Overheating and thermal runaway can result.

A short circuit causes self-heating of the battery and its temperature to rise. At elevated temperatures, above 130° C., side reactions, including a breakdown of the solid electrolyte interface layer, will occur. These reactions produce additional heat. The rates of these reactions are accelerated by increased temperature (positive feedback) and could lead to thermal runaway.

Common hazards of battery thermal runaway include offgas, smoke, fire, and even explosion. Incidents of battery system fires and explosions make news headlines. For emergency responders, existing methods of managing a battery fire use 500-8,000 gallons of water which may not always be readily available and also does not guarantee that there will not be a re-ignition later and harm nearby people and assets [see Sun, Peiyi, et al. “A review of battery fires in electric vehicles”, Fire Technology (2020): 1-50]. In the future Terawatt-hour (TWh) of aged battery packs from the automotive sector will need to be managed and recycled or refurbished and repurposed. The logistics for aggregating, transporting, sorting, and disassembling these packs will involve personnel training and gear, like the proposed headsets, for training and real-time operation, to augment the human intelligence and decision making. Moreover, the headsets can also record the human expert actions and could be used to train other personnel or robots to perform similar actions. So the headsets are not only projecting information to the user but also constantly record data for enhanced recognition and assessment of faults.

Many of the battery accidents are triggered by over-charging, overheating or with mechanical abuse [see X. Feng, M. Ouyang, X. Liu, L. Lu, Y. Xia, and X. He, “Thermal runaway mechanism of lithium ion battery for electric vehicles: A review,” Energy Storage Materials, vol. 10, pp. 246-267, 2018] which can lead to battery internal short circuit (ISC) and self-heating. At elevated temperatures, exothermic battery side reactions will become active, starting with the decomposition of the solid electrolyte interface (SEI) layer [see Spotnitz, R., and J. Franklin. “Abuse behavior of high-power, lithium-ion cells.” Journal of Power Sources 113.1 (2003): 81-100]. This leads to gas evolution that further leads to cell swelling and potentially cell rupture and gas venting. The high temperatures can lead to thermal run-away and even explosion [see Abada, Sara, et al. “Safety focused modeling of lithium-ion batteries: A review”, Journal of Power Sources 306 (2016): 178-192].

A lot of work has been done in understanding abnormal electric and thermal behavior under abnormal and faulty operation. Abnormal voltage drop of the battery [see X. Feng, M. Fang, X. He, M. Ouyang, L. Lu, H. Wang, and M. Zhang, “Thermal runaway features of large format prismatic lithium ion battery using extended volume accelerating rate calorimetry,” J. Power Sources, vol. 255, pp. 294-301, 2014; and M. Zhang, L. Liu, A. Stefanopoulou, J. Siegel, L. Lu, X. He, and M. Ouyang, “Fusing phenomenon of lithium-ion battery internal short circuit,” J. Electrochem. Soc., vol. 164, no. 12, pp. A2738-A2745, 2017], cell internal resistance change [see X. Feng, Y. Pan, X. He, L. Wang, M. Ouyang, “Detecting the internal short circuit in large-format lithium-ion battery using model-based fault-diagnosis algorithm”, Journal of Energy Storage 18 (2018) 26-39; and Feng, C. Weng, M. Ouyang, J. Sun, “Online internal short circuit detection for a large format lithium ion battery”, Applied Energy 161 (2016) 168-180], cell temperature increase [see X. Lin, H. Fu, H. E. Perez, J. B. Siegel, A. G. Stefanopoulou, Y. Ding, M. P. Castanier, “Parameterization and observability analysis of scalable battery clusters for onboard thermal management”, Oil & Gas Science and Technology—Revue d'IFP Energies nouvelles 68 (1) (2013) 165-178; and Feng, C. Weng, M. Ouyang, J. Sun, “Online internal short circuit detection for a large format lithium ion battery”, Applied Energy 161 (2016) 168-180], and abnormal current flow [see M. Zhang, J. Du, L. Liu, J. Siegel, L. Lu, X. He, M. Ouyang, “Internal short circuit detection method for battery pack based on circuit topology”, Science China Technological Sciences 61 (10)(2018) 1502-1511] can help determine a fault within a cell. However, when applied to a large battery pack, these existing methods have limitations on the signal to noise ratio, detection speed or practicality and need to be augmented and enhanced with multiple other signals.

Detecting battery faults using temperature signals or infra-thermography can cause delay of detection in large battery systems. For a battery storage depot that collects lithium-ion batteries, detection based on temperature measurement or infra-thermography can take up to hours to identify the ongoing battery thermal events [see Cai, Ting, Anna G. Stefanopoulou, and Jason B. Siegel. “Early Detection for Li-Ion Batteries Thermal Runaway Based on Gas Sensing,” ECS Transactions 89.1 (2019): 85].

Lithium intercalation and de-intercalation result in the volumetric changes in both electrodes of a lithium-ion battery cell. At the anode, carbon particles can swell by as much as 12% during lithium intercalation, and the resulting stress can be large. Commercial battery packs involve numerous cells assembled to occupy a fixed space and are held in mild compression to resist changes in volume associated with lithium intercalation and de-intercalation. A small compression prevents de-lamination and associated deterioration of electronic conductivity of the electrodes. A battery pack 30 can be assembled as shown in FIG. 1. Space between the cells 34 is maintained via a plastic spacer with dimples to preserve the airflow channels and still provide a means for compressing the cells 34 which are located between compression bars 38 and end-plates 32. Cell expansion during charging is exerted against the end-plates 32 and can be sensed by attached sensors or visually and compared against nominal behavior stored in a databases with data and/or simulation model of various batteries.

Recently measurements of the mechanical (swelling) characteristics has been proposed using acoustic signature for cells with internal faults [see Bommier, Clement, et al. “In Operando Acoustic Detection of Lithium Metal Plating in Commercial LiCoO₂/Graphite Pouch Cells,” Cell Reports Physical Science (2020): 100035]. The acoustic signatures enables probing of the density difference and thus differentiation of cell swelling due to SEI growth and gas formation which may be a precursor of catastrophic failure due to SEI thermal decomposition. The proposed effort here integrates all these signals, compares with thresholds and patterns stored, and displays integrated information via superimposed visual and audio information in a headset.

The simulation for the battery internal state and the fault evolution for a reference battery or digital twin is possible through a battery internal short circuit and thermal runaway model that discretizes the cell into three temperature sections [see Cai, Ting, Anna G. Stefanopoulou, and Jason B. Siegel. “Modeling Li-Ion Battery Temperature and Expansion Force during the Early Stages of Thermal Runaway Triggered by Internal Shorts,” Journal of The Electrochemical Society 166.12 (2019): A2431]. The prediction for the evolution of the fault is achieved through modeling the internal short circuit exothermic heat and exothermic reaction progress.

Thus, what is needed is an improved system and method for detecting, assessing, and displaying a battery fault, such as an internal short circuit in a battery cell, that could lead to battery thermal runaway.

### SUMMARY OF THE INVENTION

In one aspect, the invention provides a system for detecting and assessing a battery fault. The system comprises: a battery; a sensor for outputting a sensor signal correlating to a measurement of a chemical, electrical, or physical property of the battery; and a controller in electrical communication with the sensor and a display device. The controller is configured to execute a program stored in the controller to: (i) detect and assess a fault in the battery based on the sensor signal, and (ii) transmit a display signal to the display device such that the display device produces an image indicative of presence or absence of a fault in the battery.

In one version of the system, the display device is a headset. In one version of the system, the image is a virtual reality image. In one version of the system, the image is an augmented reality image. In one version of the system, the controller includes an image capture device that senses a QR code on the battery or a vehicle including the battery to identify a battery model and retrieve any recorded information from an external database.

In one version of the system, the sensor signal is indicative of gas generation, and/or exerted pressure, and/or a short circuit, and/or a type of the battery. In one version of the system, the display device is a headset including the controller. The display device can output information to guide a user in repairing, deactivating, suppressing, or removing the battery when a fault is detected in the battery.

In one version of the system, the controller is configured to execute a program stored in the controller to detect and assess the fault in the battery based on one or more of the sensor signals and a model of potential fault(s) in a reference battery, wherein the battery is a same type as the reference battery. In one version of the system, the model is used by the controller to determine a display signal to transmit to the display device such that the display device produces an image indicative of a level of safety and potential mitigation strategies for reducing a risk of fire for the battery. In one version of the system, the model includes data on fault(s) encountered in prior accidents for the reference battery. The data on fault(s) can include data on electric hazards. The data on fault(s) can include data on gaseous hazards. The data on fault(s) can include data on thermal hazards.

In one version of the system, the model is used by the controller to determine a display signal to transmit to the display device such that the display device produces an image indicative of safety systems and protocols to be used by first responders. In one version of the system, the model is used by the controller to determine a display signal to transmit to the display device such that the display device produces an image indicative of technician evaluations on safety from prior accidents for the reference battery. In one version of the system, the model is used by the controller to determine a display signal to transmit to the display device such that the display device produces an image indicative of guidelines and procedures to minimize exposure to dangerous conditions based on records of prior accidents and the model prediction for the reference battery.

In one version of the system, the model is used by the controller to determine a display signal to transmit to the display device such that the display device produces an image indicative of prediction of evolution of the fault(s). In one version of the system, the model is used by the controller to determine a display signal to transmit to the display device such that the display device produces an image indicative of an internal state of the battery. In one version of the system, the model is used by the controller to determine a display signal to transmit to the display device such that the display device produces an image indicative of failed cell location in the battery and a prediction of fault and battery state of health evolution with time. In one version of the system, the model is used by the controller to determine a display signal to transmit to the display device such that the display device produces an image indicative of a threshold of response safety levels for a user in case of battery fault detection.

In one version of the system, the display device outputs information to guide a user in a signal excitation for creating a signal response to be sensed by the sensor for outputting the sensor signal to the controller to detect and assess the fault in the battery. The signal excitation can be selected from electrochemical impedance spectroscopy signals, acoustic signals, infra-red signals, and thermography signals.

In one version of the system, the controller includes an image capture device that senses a visual aspect of the battery or a vehicle including the battery to identify a battery model and retrieve any recorded information from an external database.

In another aspect, the invention provides a method for detecting and assessing a battery fault. The method can comprise the steps of: (a) receiving in a controller a sensor signal correlating to a measurement of a chemical, electrical, or physical property of a battery, the controller being in electrical communication with a display device; (b) detecting and assessing in the controller a fault in the battery based on the sensor signal; and (c) transmitting a display signal from the controller to the display device such that the display device produces an image indicative of presence or absence of a fault in the battery.

In one version of the method, the display device is a headset. In one version of the method, the image is a virtual reality image. In one version of the method, the image is an augmented reality image.

The method can further comprise sensing a QR code on the battery or a vehicle with an image capture device of the controller to identify a battery model and retrieve any recorded information from an external database. The method can further comprise sensing a visual aspect of the battery or a vehicle with an image capture device of the controller to identify a battery model and retrieve any recorded information from an external database.

In one version of the method, the sensor signal is indicative of gas generation, and/or exerted pressure, and/or a short circuit, and/or a type of the battery. In one version of the method, the display device outputs information to guide a user in repairing, deactivating, suppressing, or removing the battery when a fault is detected in the battery. In one version of the method, the display device outputs information to a user with projections of any internal evolving fault(s) along with the prediction for the evolution of the battery fault and the guiding towards safe interventions. In one version of the method, the controller is configured to execute a program stored in the controller to detect and assess the fault in the battery based on the sensor signal and a model of potential fault(s) in a reference battery, wherein the battery is a same type as the reference battery. The model can be used by the controller to determine a display signal to transmit to the display device such that the display device produces an image indicative of a level of safety and potential mitigation strategies for reducing a risk of fire for the battery. In one version of the method, the model includes data on fault(s) encountered in prior accidents for the reference battery. In one version of the method, the data on fault(s) includes data on electric hazards. In one version of the method, the data on fault(s) includes data on gaseous hazards. In one version of the method, the data on fault(s) includes data on thermal hazards.

In one version of the method, the model is used by the controller to determine a display signal to transmit to the display device such that the display device produces an image indicative of safety systems and protocols to be used by first responders. In one version of the method, the model is used by the controller to determine a display signal to transmit to the display device such that the display device produces an image indicative of technician evaluations on safety from prior accidents for the reference battery. In one version of the method, the model is used by the controller to determine a display signal to transmit to the display device such that the display device produces an image indicative of guidelines and procedures to minimize exposure to dangerous conditions based on prior accidents for the reference battery.

In one version of the method, the model is used by the controller to determine a display signal to transmit to the display device such that the display device produces an image indicative of prediction of evolution of the fault(s). In one version of the method, the model is used by the controller to determine a display signal to transmit to the display device such that the display device produces an image indicative of an internal state of the battery. In one version of the method, the model is used by the controller to determine a display signal to transmit to the display device such that the display device produces an image indicative of failed cell location in the battery and a prediction of fault and battery state of health evolution with time. In one version of the method, the model is used by the controller to determine a display signal to transmit to the display device such that the display device produces an image indicative of a threshold of response safety levels for a user in case of battery fault detection.

In one version of the method, the display device outputs information to guide a user in a signal excitation for creating a signal response to be sensed by the sensor for outputting the sensor signal to the controller to detect and assess the fault in the battery. The signal excitation can be selected from electrochemical impedance spectroscopy signals, acoustic signals, infra-red signals, and thermography signals.

In another aspect, the invention provides a training system comprising: a display device; and a controller in electrical communication with the display device. The controller is configured to execute a program stored in the controller to: (i) transmit a display signal to the display device to produce on the display device an image of a battery having a fault, and a user guide for repairing, deactivating, suppressing, or removing the battery fault.

In one version of the training system, the display device is a headset. In one version of the training system, the image is a virtual reality image. In one version of the training system, the image is an augmented reality image.

In one version of the training system, the controller includes an image capture device that senses a QR code on a battery or a vehicle including the battery to identify a battery model and retrieve any recorded information from an external database. In one version of the training system, the fault is gas generation and/or a short circuit. In one version of the training system, the display device is a headset including the controller.

In another aspect, the invention provides a method for training a user on repairing, deactivating, suppressing, or removing a battery fault. The method comprises transmitting a display signal from a controller to a display device to produce on the display device an image of a battery having a fault, and a user guide for repairing, deactivating, suppressing, or removing the battery fault. In one version of the training method, the display device is a headset. In one version of the training method, the image is a virtual reality image. In one version of the training method, the image is an augmented reality image.

The training method can further comprise sensing a QR code on a battery or a vehicle including the battery with an image capture device of the controller to identify a battery model and retrieve any recorded information from an external database. The training method can further comprise sensing a visual aspect of the battery or a vehicle with an image capture device of the controller to identify a battery model and retrieve any recorded information from an external database. The fault can be gas generation and/or a short circuit. In one version of the training method, the display device is a headset including the controller.

One version of the invention includes safe goggles that are a virtual reality (VR) headset to be used for emergency responders for an electric vehicle fire. From the vehicle's internal sensor signal which may come from a battery management system or a sensor in the battery, the safe goggles project the unseen internal evolving faults of battery systems and vehicles to the first responders. The electric, gaseous, thermal hazards inside the electric vehicle can be shown using virtual reality to inform the first responder, along with the prediction for the evolution of the battery fault and the guiding towards safe interventions. The safe goggles will guide first responder in moving fast to remove injured persons but also dispose damaged packs safely.

One version of the invention includes a training tool that could be used to simulate battery faults. The goggles can be used for education and demonstrations of safe battery handling.

These and other features, aspects, and advantages of the present invention will become better understood upon consideration of the following detailed description, drawings and appended claims.

### BRIEF DESCRIPTION OF THE DRAWINGS

FIG. 1 shows a drawing of battery cells under compression in a hybrid electric vehicle battery pack.

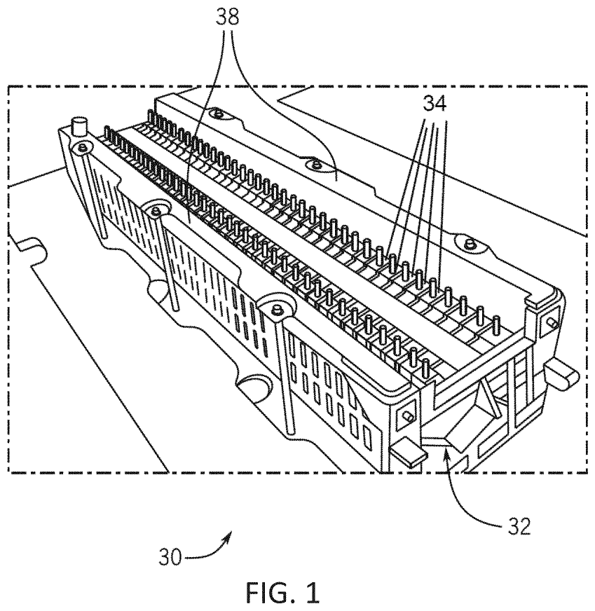

FIG. 2 is a schematic showing an exploded perspective view of a fixture used in the device of U.S. Patent Application Publication No. 2020/0313152.

FIG. 3 is a schematic illustration of a block diagram of a system for detecting and assessing a battery fault.

FIG. 4 is a flowchart of a process for detecting a battery fault of a battery.

### DETAILED DESCRIPTION OF THE INVENTION

The term “fault” refers to a condition that develops in an electrochemical device, such as a battery, that is indicative of non-routine, non-optimal, dangerous or otherwise unexpected or unwanted behavior in the electrochemical device. In one non-limiting example, a fault refers to an electrical cutoff in an electrochemical device. In another non-limiting example, a fault refers to an electrical short circuit in an electrochemical device. In another non-limiting example, a short circuit can develop between various components of an electrochemical device, such as between an anode current collector and a cathode current collector, or between an anode active material and a cathode active material, or between an anode current collector and a cathode active material or between an anode active material and a cathode current collector. In another non-limiting example, a fault refers to a state of health or change in state of health of an electrochemical device indicative of a decrease in operational performance, such as an increase in internal resistance, a capacity loss or an inability to undergo charge cycling. In another non-limiting example, a fault refers to gas generation due to breakdown of the cell electrode materials.

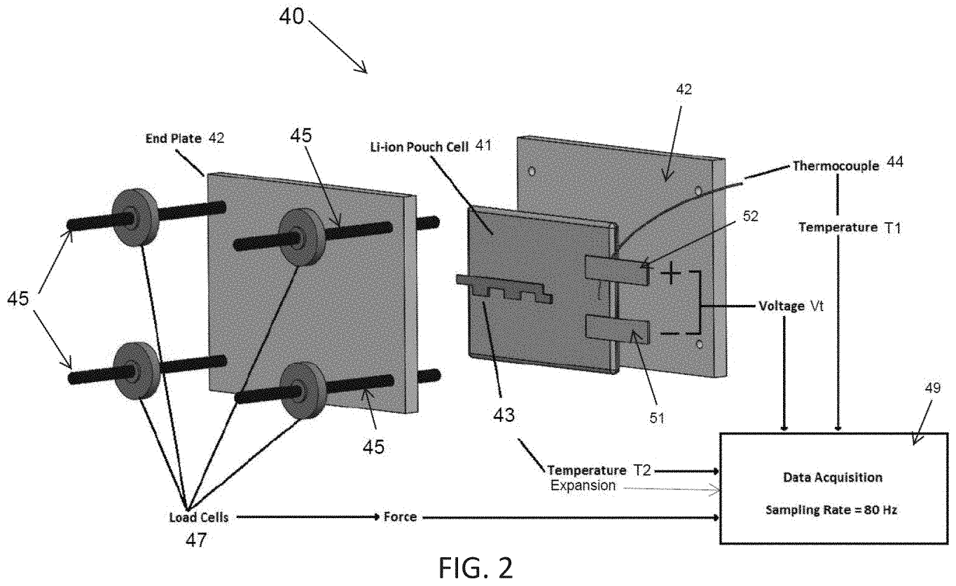

To provide context for this invention, example methods for gas generation detection and/or internal short circuit detection can be found in U.S. patent application Ser. No. 16/410,714 which published as U.S. Patent Application Publication No. 2020/0313152 to Stefanopoulou et al., which is incorporated herein by reference. U.S. 2020/0313152 describes a system for high confidence detection of gas generation and/or an internal short circuit in batteries, such as lithium ion batteries. U.S. 2020/0313152 describes that a fixture 40 such as that shown in FIG. 2 can be used to obtain force measurements of a battery at various temperatures and states of charge for the battery. In FIG. 2, a fixture 40 is shown wherein an NMC-graphite pouch cell 41 is placed between two fiberglass-epoxy composite plates 42. A temperature and expansion sensor 43 with six temperature sensing elements is placed on the pouch cell 41. A thermocouple 44 is placed between current collecting tabs 51, 52 of the NMC-graphite pouch cell 41 at the position where the venting will occur. The plates 42 allow for compression of the pouch cell 41 and the plates 42 are bolted together using four bolts 45, one in each corner of the plate 42. Each of the four bolts 45 is instrumented with a strain gauge load cell 47. The cell temperature T1 from thermocouple 44, the cell temperature T2 from the temperature and expansion sensor 43, the terminal voltage Vt, and force are sampled at an 80 Hz rate as shown at block 49 in FIG. 2. An internal short circuit can lead to local heating and gas generation, which results in battery swelling before the elevated temperature could reach to the surface of the cell. A measured voltage can exhibit an initial drop but subsequently can raise again. Accumulated pressure inside the cell can cause the pouch cell 41 to rupture between the current collecting tabs 51, 52, and timing of the event can be observed by rapid depressurization. Also, the thermocouple temperature T1 can increase due to hot gases venting out over the thermocouple 44 placed between the current collecting tabs 51, 52. An internal short circuit event and the eventual rupture can be detected using measured force earlier than using temperature sensors on the surface of the battery.

Thus, U.S. 2020/0313152 reports that force measurements obtained using one or more pressure sensors that convert a level of pressure into an electrical signal, such as load sensors outside a battery pack having one or more cells, or one or more strain sensors attached on the surface of an electrode of a battery cell, exhibit a distinct increase in measured electrical output of the pressure sensor at the same time with the occurrence of an internal short circuit. The electrical signals from these pressure sensor(s) can alone, or in combination with other battery measurements (e.g., voltage, temperature, current, specific gravity, battery type, capacity), increase the confidence level of gas generation and/or internal short circuit detection before the battery cell ruptures and well before any significant increase in the measured battery cell surface temperature. Reducing the probability of detecting a false positive is important due to the extreme measures that sometimes are needed to contain the damage of a damaged battery cell from spreading to other battery cells in the battery pack. Such extreme measures may include ejecting the cell or flooding the entire battery pack with an inert material.

Similar to U.S. 2020/0313152, a system of the present invention may include a battery and an electronic controller. The controller may include a microprocessor under the control of a software program stored in the controller memory. The battery can be a lithium ion battery pack. The battery pack may include a single cell or a plurality of cells. The battery pack may include a plurality of prismatic cells. Each prismatic cell may comprise a positive electrode selected from lithium nickel manganese cobalt oxide, lithium manganese oxide, and lithium iron phosphate, a negative electrode selected from graphite, lithium titanate, hard carbon, tin/cobalt alloy, and silicon carbon, and an electrolyte selected from lithium salts such as LiPF₆, LiBF₄, and LiClO₄. A system of the present invention may include components such as those in U.S. 2020/0313152 for gas generation detection and/or internal short circuit detection in a battery. However, the components of a system of the present invention that allow for detection of a fault in the battery are not limited to the non-limiting examples exemplified in U.S. 2020/0313152.

In the event of an electric vehicle (EV) crash or failure of the charging system, damage to the Li-ion battery pack may result in exothermic reactions and venting gas species, which can lead to flame or explosion if exposed to an ignition source. In order to ensure the safety of first responders on the scene of an EV crash or fire fast and high confidence level detection of the state of safety (SOS) for the vehicle battery pack is needed. False positive detections are also undesirable as many thermal runaway mitigation techniques, such as activating pyrotechnic safety switches, would disable the vehicle.

A method of the present invention evaluates past electric vehicle accidents (some of them when parked and not even charging), safety systems and protocols used by first responders and/or technicians to evaluate the safety of the battery pack and how to synthesize guidelines and procedures to minimize the exposure to dangerous conditions. Based on this analysis, new protocols are provided for first responders which utilize a combination of physics-based models and signals from the battery pack including the gas detection sensors (such as described in U.S. 2020/0313152) to evaluate damage to the individual cells within the pack. These models can be used to help advise first responders to the level of safety and potential mitigation strategies for reducing the risk of a battery fire. Virtual reality (VR) or augmented reality (AR) headsets with projections of the internal evolving fault(s) along with guiding towards safe interventions (assuming electric, gaseous, thermal hazards) can guide the first responder in moving fast to remove injured persons but also dispose safely damaged packs.

In one example non-limiting example of a system of the present invention, the system includes a battery and a controller in wired or wireless electrical communication with a display device and a sensor that outputs a sensor signal correlating to a measurement of a chemical, electrical, or physical property of the battery. The controller is configured to execute a program stored in the controller to: (i) detect and assess a fault in the battery based on the sensor signal, and (ii) transmit a display signal to the display device such that the display device produces an image indicative of the presence or the absence of a fault in the battery. The display device and the controller may be incorporated into safe goggles that enable the diagnosis of the battery fault(s) based on a variety of signals from the battery management system (BMS), OEM signals or other methods, for example, QR code through the blockchain.

Through sensor fusion of the available information from the BMS, radio frequency identification (RFID) tag, or a QR code or a signal excitation response, the safe goggles of a system of the present invention can project to the user the prediction of the evolution of the specific battery fault(s). The safe goggles have access to a large database of various battery packs and battery models to analyze the internal state of the inspected battery pack. The controller may be incorporated into the goggles and may include memory storage which may store the database of various battery packs and battery models used to analyze the internal state of the inspected battery pack. The database of various battery packs and battery models provides a number of reference batteries having battery data or a simulation model.

In one example non-limiting example, the controller may include a receiver that receives at least one unique radio frequency signal transmitted from a radio frequency identification (RFID) tag on the battery or vehicle to identify the battery model. The RFID tag acts as a sensor for outputting a sensor signal correlating to a measurement of a chemical, electrical, or physical property of the battery. In one example non-limiting example, the controller may include an image capture device that senses the QR code (or bar code) on the battery or vehicle to identify the battery model and retrieve any recorded information from external database(s). The QR code acts as a sensor for outputting a sensor signal correlating to a measurement of a chemical, electrical, or physical property of the battery.

The headset can also analyze all the possible visual features of the battery (be it a pack, module, cell stand-alone or inside a vehicle and partially visible). The visual signal that may include QR code or a blockchain identifier will be sent to the controller that has a recognition routine and search in a database for a reference battery or family of batteries. The controller will establish a confidence level based on which it may require additional measurements beyond the visual information and guide the user to perform safely these measurements given the accessibility to the pack, modules and cells. One can use image recognition algorithm to identify the pack from a stored database of images. The QR code can be a static image which redirects the user to a website where the data can be retrieved and has been validated by blockchain. The battery type can be available through an online database, using stored information (provided by the manufacturer).

Lithium ion batteries are widely used in energy storage and offer significant improvements in electric vehicles. However, the growth in battery energy density increases the risk and severity of battery failures. With the increasing numbers of electric vehicles and consumer electronics applications of large capacity Li-ion batteries, battery fires, and explosions accidents are increasing worldwide. Many of these accidents start with an overcharge, over-discharge, or a battery separator penetration due to mechanical abuse that lead to battery temperature elevation, self-heating and finally thermal runaway. In many cases, this process begins with an internal short circuit that causes self-heating and can elevate the battery temperature above 130° C. This in turn can result in side reactions, including a breakdown of the Solid Electrolyte Interface layer. These side reactions quickly produce additional heat and can lead to battery thermal runaway. Common hazards of battery thermal runaway include toxic off gassing, smoke, fire, and even an explosion. To develop an early detection method, it is important to model the thermal runaway process of a specific battery. An example model can include one or any combination of: an electrical model for the internal short circuit process, a side reactions model for exothermic reactions of active materials, a thermal model for battery temperature, and a gas evolution model to predict early gas generation. These models are non-limiting examples of the models that can be stored in the database as reference batteries for the prediction of the evolution of the specific battery fault(s) in the present invention.

If the data is not available or not sufficient, the goggles can guide the users to follow protocols to have signal excitations for the pack and help diagnose the pack. Examples of such a testing technique to extract additional data are Electrochemical Impedance Spectroscopy (EIS), acoustic, infra-red, thermography.

For a damaged battery pack, the safe goggles can project the analysis of the available diagnosis data obtained through a battery system model integrated with a data library, to estimate the failed cell location and predict the fault and battery State of Health (SOH) evolution with time. The prediction can be streamed and projected in superimposed virtual-reality or augmentation of the actual visual from the safe goggles. The user is able to set a threshold of safety levels in case of battery failure incidents to better inform critical personnel in disassembly lines in various recycling or repurposing facilities and first responders of the time they have to deactivate, suppress, or remove the failing battery.

The safe goggles can be virtual reality (VR) headsets to be used for emergency responders for an electric vehicle fire. From the vehicle's internal sensor signal, the safe goggles project the unseen internal evolving faults of battery systems and vehicles to the first responders. The electric, gaseous, thermal hazards inside the electric vehicle can be shown using virtual reality to inform the first responder, along with the prediction for the evolution of the battery fault and the guiding towards safe interventions. The safe goggles guide the first responder in moving fast to remove injured persons but also dispose damaged packs safely.

One non-limiting example use of the system of the present invention can be described as follows. A first responder at an electric vehicle accident can put on a virtual reality headset according to the invention, and the controller of the virtual reality headset can receive a sensor signal transmitted from a sensor in the battery or the battery management system of the electric vehicle. As non-limiting examples, the sensor signal can indicate gas generation from the battery (such as by using the methods of U.S. 2020/0313152), and/or the sensor signal can indicate a short circuit in the battery (such as by using the methods of U.S. 2020/0313152), and/or the sensor signal can indicate the battery type. The controller can transmit a display signal to the display of the virtual reality headset such that the display of the virtual reality headset produces an image indicative of the presence or the absence of a fault (e.g., gas generation, a short circuit) in the battery. The controller could also transmit a display signal to the display of the virtual reality headset such that the display of the virtual reality headset produces an image guiding the first responder towards safe interventions based on the sensor signal indicating the battery type and data on various battery types in a database in the memory storage of the controller.

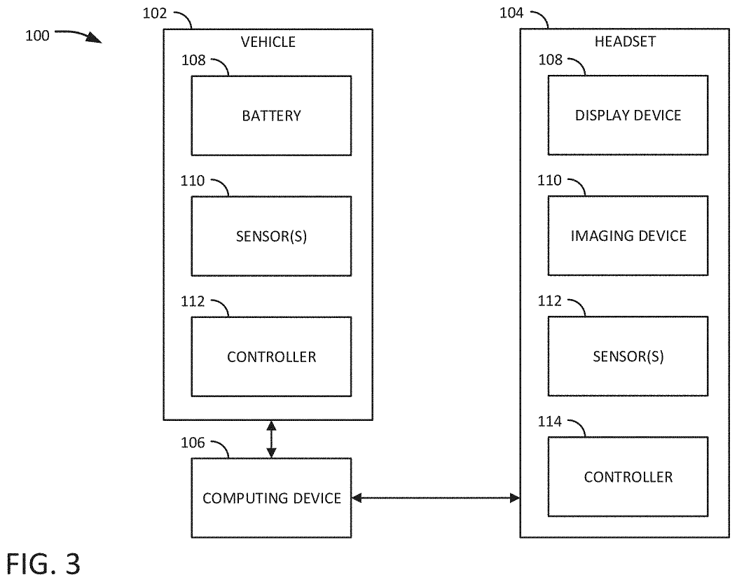

FIG. 3 shows a schematic illustration of a block diagram of a system 100 for detecting and assessing a battery fault. The system 100 can include a vehicle 102, a headset 104, and a computing device 106. The vehicle 102 can be implemented in different ways. For example, the vehicle 102 can be an all-electric vehicle, a hybrid vehicle, or a traditional internal combustion vehicle. In addition, the vehicle 102 can be a truck, a sedan, a material handling vehicle, etc. Thus, the battery 108 can supply power to various electrical loads of the vehicle 102 including, for example, a motor, engines (e.g., spark plugs of an engine), auxiliary electrical loads (e.g., a radio), etc. In some non-limiting examples, the vehicle 102 can include a battery 108, one or more sensors 110 associated with the battery 108, and a controller 112.

The battery 102 can be implemented in different ways. For example, the battery 102 can include one or more individual battery cells that are electrically connected together (e.g., in series, in parallel, combinations thereof, etc.) and are positioned within a battery housing of the battery 102. In some cases, the one or more battery cells can be lithium ion cells, lead-acid cells, etc. In some non-limiting examples, the one or more sensors 110 can be associated with the battery 108. For example, each sensor 110 can be configured to sense a chemical, an electrical, or a physical property of the battery 102. In some cases, each sensor 110 can be configured to sense a chemical, an electrical, or a physical property for each individual battery cell of the battery 102. In other cases, each sensor 110 can be configured to sense a chemical, an electrical, or a physical property for a group of individual battery cells of the battery 102, including all the individual battery cells of the battery 102.

In some non-limiting examples, the one or more sensors 110 can be implemented in various different ways. For example, the one or more sensors 110 can include a temperature sensor, a gas sensor, a voltage sensor, a current sensor, an impedance sensor, a pressure sensor, an acoustic sensor, etc., for each individual battery cell of the battery 108, or for a collection of battery cells of the battery 108, or both. As a more specific example, the sensors 110 can include a temperature sensor in thermal communication with each individual battery cell of the battery 108, and a temperature sensor in thermal communication with an internal volume of the battery 108 that includes the one or more battery cells. In this way, temperature sensors can monitor the temperature of the individual battery cells, and the battery 108, to determine undesirable increases in the temperature indicative of a fault for the battery 108. In some cases, the temperature sensor can be a thermocouple, a thermistor, etc.

As another more specific example, the sensors 110 can include a gas sensor in fluid communication with the interior volume of each individual battery cell (e.g., assuming each battery cell is enclosed within a corresponding battery cell housing), and a gas sensor in fluid communication with the interior volume of the housing of the battery 108 (e.g., that encloses and supports the one or more battery cells of the battery 108). In this way, each gas sensor can determine undesirable increases in gasses produced by the battery 108 (e.g., individual cells of the battery 108) that are indicative of a fault for the battery 108. In some cases, each gas sensor can be a combustible gas sensor, which can be configured to sense an amount of combustible gasses (e.g., a concentration of combustible gasses) that is in fluid communication with the combustible gas sensor. In this case, the combustible gas sensor can be a catalytic sensor (e.g., in which increases in resistance are indicative of combustible gas species), an infrared sensor (e.g., including a detector and a receiver), etc. In other cases, a gas sensor can be a pressure sensor, in which the generation of gaseous species by the battery 108 is indicative of pressure increases sensed by the pressure sensor (e.g., when the gas sensor is enclosed within the housing of the batter 108).

As yet another more specific example, the sensors 110 can include a voltage sensor electrically connected to each individual battery cell, or the entire battery 108. For example, each voltage sensor can be electrically connected to the anode or the cathode of each individual battery cell to sense the voltage provided by the respective individual battery cell. In addition, a voltage sensor can be electrically connected to the anode or the cathode of the battery 108 to sense the voltage provided by the entire battery 108. In this way, the present voltage sensed by each voltage sensor can be indicative of a short circuit within an individual cell of the battery 108 to indicate a fault (e.g., an electrical fault) within the individual cell, or the entire battery 108 to indicate a fault within the battery 108. For example, a drop in the present voltage (e.g., below a threshold value) of a battery cell (or the entire battery 108) can be indicative of a short circuit of the battery cell (or the entire battery 108).

As still yet another more specific example, the sensors 110 can include a current sensor electrically connected to each individual battery cell, or the entire battery 108. For example, each current sensor can be electrically connected to the anode or the cathode of each individual battery cell to sense the current provided by the respective individual battery cell. In addition, a current sensor can be electrically connected to the anode or the cathode of the battery 108 to sense the current provided by the entire battery 108. In this way, a change (e.g., an abnormal abrupt change) in the present current sensed by each current sensor can be indicative of a short circuit in each individual battery cell (e.g., because the current can, at times, short circuit thereby decreasing the current sensed by the current sensor). Correspondingly, a change in the present current sensed by a current sensor can be indicative of a short circuit in the entire battery 108.

As yet another more specific example, the sensors 110 can include an impedance sensor electrically connected to each individual battery cell, or the entire battery 108. For example, each impedance sensor can be electrically connected across the anode and the cathode of each individual battery cell to sense the impedance between the anode and cathode of the respective individual battery cell (e.g., the impedance of the individual battery cell). In addition, an impedance sensor can be electrically connected across the anode and the cathode of the entire battery 108 to sense the impedance across the anode and the cathode of the battery 108 (e.g., the impedance of the entire battery 108). In some cases, a resistance sensor can be replaced with an impedance sensor. For example, the resistance sensor can be a voltage sensor and a current sensor, and a controller can determine the resistance by dividing the present voltage by the present current. In some cases, although each impedance sensor can determine the impedance across an electrical load (e.g., an individual battery cell) by varying the frequency of the electrical signal applied to the electrical load, each impedance sensor can also determine the resistance of the electrical load by applying a substantially (i.e., deviating by less than 10 percent) direct current electrical signal to the electrical load. Regardless of the configuration, decreases in the impedance (or resistance) of an individual battery cell (or the entire battery 108) can be indicative of short circuiting of the individual battery cell or the entire battery 108.

As yet another more specific example, the sensors 110 can include a pressure sensor within each housing of each individual battery cell (e.g., with the pressure sensor enclosed within the individual battery cell), or the entire battery 108 (e.g., the pressure sensor enclosed within the housing of the battery 108 that contains the individual cells). In other cases, the sensors 110 can include a pressure sensor each of which is in contact with and external to a respective individual battery cell. In addition, the sensors 110 can include a pressure sensor that is in contact with and external to the entire battery 108. Regardless of the configuration, the pressure sensors can sense large mechanical impacts of the individual cell (or the entire battery 108) that can be indicative of damage to the individual cell (or the entire battery 108) to indicate a fault. In some cases, including when a pressure sensor is enclosed within a housing of an individual battery cell (or the entire battery 108), increases in pressure can be indicative of the generation of combustible gasses from the battery, which can thus indicate a fault. In some non-limiting examples, the pressure sensor can be a strain gauge, a piezoelectric pressure sensor, etc.

As still yet another specific example, the sensors 110 can include an acoustic sensor within each housing of each individual battery cell (e.g., with the acoustic sensor enclosed within the individual battery cell), or the entire battery 108 (e.g., the acoustic sensor enclosed within the housing of the battery 108 that contains the individual cells). In other cases, the sensors 110 can include an acoustic sensor positioned external to the battery 108, which can sense acoustic waves produced by the entire battery 108, which can be indicative of a fault in the battery 108. In one example, acoustic signals that have a relatively high frequency and amplitude can be indicative of combustible gasses escaping from the battery 108 thereby indicating a fault. In another example, a system including an acoustic transducer and receiver can sense accumulating gasses due to changes in amplitude and/or wave speed of reflected acoustic waves. In another example, an acoustic sensor may detect waves indicative of a pressure release from a safety device that vents gasses from a battery cell. In some non-limiting examples, the acoustic sensor can be a piezoelectric, capacitive based, a microphone, etc.

As shown in FIG. 3, the controller 112 can be in communication with the battery 108 (e.g., with the battery 108 supplying power to the controller 112), and each of the sensors 110. Thus, the controller 112 can be implemented in a variety of different ways. For example, the controller 112 can be implemented as known types of processor devices, (e.g., microcontrollers, field-programmable gate arrays, programmable logic controllers, logic gates, etc.), including as part of general or special purpose computers. In addition, the controller 112 can also include other computing components, including memory, inputs, output devices, etc. (not shown). In this regard, the controller 11212 can be configured to implement some or all of the operations of the processes described herein, which can, as appropriate, be retrieved from memory. For example, the controller 112 can receive sensor signals from each sensor 110, can analyze the sensor signals to determine the presence of a battery fault, etc. In some non-limiting examples, the controller 112 can include multiple control devices (or modules) that can be integrated into a single component or arranged as multiple separate components.

In some non-limiting examples, the computing device 106 can be implemented in a similar manner as the controllers described herein (e.g., the controller 112). For example, the computing device 106 can include typical computing components, such as, a processor device, memory, communication systems, a display, inputs (e.g., a mouse, a keyboard, a touch screen, sensors, and the like), power sources, etc. In some cases, the computing device 106 can take on a variety of specific forms including a desktop, a laptop, a mobile device (e.g., a tablet, or a smartphone), a server, etc. As shown in FIG. 3, the computing device 106 is in communication (e.g., bidirectional communication) with the vehicle 102 and the headset 104. In particular, the computing device 106 can be in communication with the controller 112 and the controller 114. Similarly to the controller 112, the computing device 106 can also implement some (or all) of the processes described herein. For example, the computing device 106 can store a database full of battery types, each of which can be associated with a vehicle type (e.g., model, brand, etc.), and one or more models of the battery type (e.g., a physics-based model, a model of types of faults with each type having a corresponding threshold and corresponding conditional logic, etc.).

As shown in FIG. 3, the headset 104 (e.g., an augmented reality headset) can include a display device 108, an imaging device 110, one or more sensors 112, and a controller 114. The display device 108 can be implemented in different ways. For example, the display device 108 can be coupled to glasses to project one or more images to a user's eyes, can be a stereoscopic head-mounted display to project to a user a 3D image scene, etc. The imaging device 110 can be implemented in different ways. For example, the imaging device 110 can include an imaging sensor (e.g., a charge-coupled device CCD), which can be a one-dimensional imaging sensor or a two-dimensional imaging sensor. The imaging device 110 can include other optical components (e.g., lenses, prisms, etc.) to facilitate appropriate acquisition of imaging data. Regardless of the configuration of the imaging device 110, the imaging device 110 can be configured to acquire imaging data of a symbol (e.g., a barcode, a QR code, a data matrix, etc.) coupled (or otherwise associated) with the battery 108, imaging data of the battery 108, or imaging data of the vehicle 102. This imaging data can then be analyzed (e.g., by the controller 114) to determine a battery type for the battery 108, which can include a make (e.g., a brand), a model-year, etc., of the battery 108. Then, as described in more detail below, one or more models associated with the battery type can be retrieved and can be utilized for determination of a fault for the battery 108.

In some non-limiting examples, the sensor(s) 112 can be implemented in a similar manner as the sensors 110, as appropriate. For example, the sensors 112 can include an impedance sensor, a temperature sensor, a pressure sensor, etc. In some cases, the temperature sensor can be an infrared-based temperature sensor (e.g., so that the user can be positioned at a safer distance away from the battery 108). For example, the infrared-based temperature sensor can be an infra-thermography sensor (e.g., an infrared camera), which can acquire a thermal image of the battery 108). In some non-limiting examples, the sensors 112 can include other sensors, such as, for example, motion tracking sensors (e.g., gyroscopes, accelerometers, magnetometers, etc.) to track the position and orientation of the headset 104 relative to a reference object.

In some non-limiting examples, the controller 114 can be implemented in a similar manner as the controller 112. In addition, the controller 112 can be in communication with the display device 108, the imaging device 110, and each of the sensors 112. Thus, the controller 112 can receive sensor signals from each of the sensors 112, receive imaging data from the imaging device 110, present information (e.g., graphics, images, etc.) on the display device 108, etc.

While the system 100 illustrates the battery 108 (the sensors 110, and the controller 112) as being part of the vehicle 102, in other non-limiting examples, the battery 108 (the sensors 110, and the controller 112) can be part of a different device. For example, the battery 108 (the sensors 110, the controller 112) can be part of a computer, a tablet, a smartphone, a generator (e.g., a wind turbine, a solar power generator, etc.), a power distribution system (e.g., with the battery 108 providing power to the power distribution system, such as one that provides power to a single house, multiple houses, etc.), etc. In addition, while the system 100 illustrates the display device 108 (and other components of the headset 104 including the imaging device 110) as being part of the headset 104, in other non-limiting examples, the display device 108 and other components of the headset 104 can be separate from the headset 104. For example, the display device 108 can be separate from the headset 104 and can be a standalone display device (e.g., on a smartphone). In this case, for example, the display device 108 can be an liquid crystal display (“LCD”), a light emitting diode (“LED”) display, an organic LED display, etc. As another example, the imaging device 110 can be separate from the headset 104 (e.g., being a standalone camera). In some non-limiting examples, however, there can be advantages to having the headset 104 include the display device 108 and the imaging device 110 (e.g., the display device 108 and the imaging device 110 coupled to the headset 104). For example, in an emergency situation (e.g., the crashing of the vehicle 102) the headset 104 can be deployed more quickly rather than the standalone devices (e.g., a separate display device, a separate imaging device, etc.), which can allow for faster determination of faults and subsequent mitigations of the fault(s) (e.g., disconnecting the battery 108).

In some non-limiting examples, some (or all) of the components of the system 100 can be a training system for training a user on repairing, deactivating, suppressing, or removing a battery fault. For example, the training device can include the display device 108, the imaging device 110, the controller 114, etc.

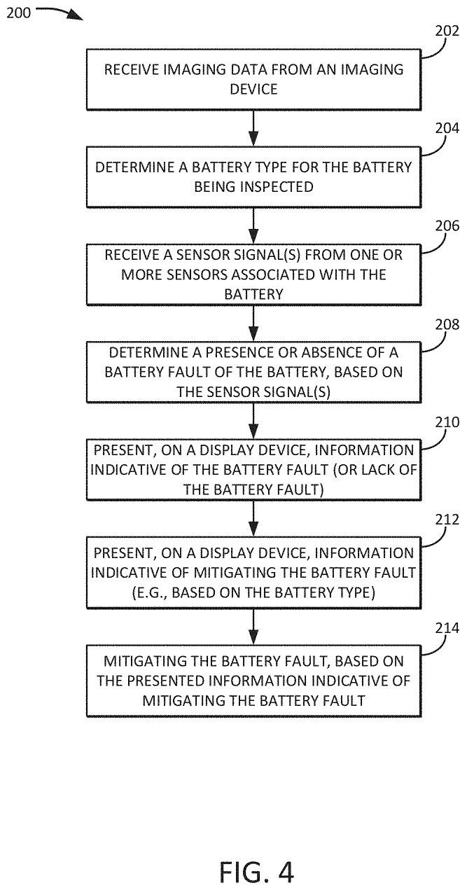

FIG. 4 shows a flowchart of a process 200 for detecting a battery fault of a battery (e.g., of a vehicle such as an all-electric vehicle) to be inspected, which can include mitigating the detected battery fault. The process 200 can be implemented using one or more computing devices (e.g., the controllers 112, 114, the computing device 106, etc.), In addition, the process 200 can be implemented using the system 100.

In some non-limiting examples, the process 200 can be for training a user on repairing, deactivating, suppressing, or removing a battery fault. Thus, some (or all) blocks of the process 200 can be for training a user. In some cases, portions of the process 200, rather than being physical and tangible objects can be virtual objects that are presented to the display device of the user and are interacted with by the user in a virtual reality environment. For example, a computing device can present, on a display device, an image of a battery having a fault. As another example, a computing device can present, on the display device, information indicative of mitigating the battery fault. As yet another example, a computing device can acquire a virtual image (e.g., from the user interacting in the virtual environment) with a virtual image capture device (e.g., based on receiving a user input to acquire the virtual image), which can be of, for example, a symbol on (or associated with) the battery to identify the battery type.

At 202, the process 200 can include a computing device receiving imaging data from an imaging device (e.g., the imaging device 110). In some cases, the imaging data can be of a symbol associated with a battery (e.g., coupled to the battery), which can be a barcode, a data matrix, etc. In some cases, the imaging data can be of the battery, of the device that receives power from the battery (e.g., of the vehicle), etc. In some cases, including when the battery is part of a vehicle, the imaging data can be of a vehicle identification number (“VIN”) of the vehicle. In other cases, a computing device can receive a user input indicative of the VIN (or other vehicle identification).

At 204, the process 200 can include a computing device determining a battery type for the battery being inspected. In some cases, this can include a computing device determining the battery type for the battery, based on the imaging data (e.g., received at the block 202). For example, this can include a computing device decoding the imaging data of a symbol to generate decoded battery information (e.g., a product code). Then, a computing device can determine the battery type, based on the decoded battery information (e.g., by querying a look-up table that includes the battery type associated with the battery information). As another example, this can include a computing device analyzing the imaging data of the battery to determine a battery type of the battery. In some cases, this can include reconstructing one or more images of the battery from the imaging data and comparing the one or more images to one or more previously acquired images of batteries of different battery types to identify a match between the battery and a specific battery type. In some cases, comparing the one or more images can include determining common features (e.g., shapes of structures of the battery) between the one or more images of the battery and one or more images of different types of batteries. As yet another example, this can include a computing device analyzing the imaging data of the vehicle that includes the battery to determine a battery type of the battery. This process can be similar to the above process for determining the type of battery based on image analysis. For example, a computing device can compare one or more images reconstructed from the imaging data to one or more previously constructed images of vehicles of different types to identify a match between the vehicle and a specific vehicle type. In some cases, comparing the one or more images can include determining common features (e.g., shapes of structures of the vehicle) between the one or more images of the vehicle and one or more images of different types of vehicles. Then, in some cases, a computing device can determine a battery type, based on the (determined) type of vehicle. For example, a computing device can query a look-up table that includes different types of vehicles each associated with a respective battery type to determine the battery type, given the vehicle type.

In some non-limiting examples, including when a computing device receives a VIN for the vehicle that includes the battery, a computing device can determine the battery type based on the VIN for the vehicle. For example, a computing device can query a database that includes different VINs with corresponding battery types associated therewith to determine the battery type given the VIN.

In some non-limiting examples, the block 204 can include receiving one or more models associated with the (determined) battery type of the battery. In some cases, the one or more models can include different criteria, which can be different for each different type of battery (e.g., the year-model, the brand, etc.). For example, a model for the battery type of the battery can include a threshold for each different sensed parameter used to determine the presence (or lack of) a battery fault for an individual battery cell of the battery or the entire battery. Thus, the thresholds can include a temperature threshold, a voltage threshold, a current threshold, an impedance threshold, a resistive threshold, a gas threshold, a pressure threshold, an acoustic threshold, etc., for an individual battery cell, and for the entire battery (e.g., with the thresholds being different for the entire battery than the individual battery cell). In addition to the thresholds, the model can include corresponding conditional logic, which can determine the presence (or lack of) a battery fault. For example, a temperature value higher than the temperature threshold can indicate a fault (and vice versa), a voltage value lower than the voltage threshold can indicate a fault (and vice versa), a current value that exceeds the current threshold can indicate a fault, an impedance value that is lower than the impedance threshold can indicate a fault (and vice versa), a resistance value that is lower than the resistance threshold can indicate a fault (and vice versa), a gas value that is greater than a gas threshold (e.g., a gas concentration or amount) can indicate a fault (and vice versa), a pressure threshold that is greater than a pressure threshold can indicate a fault (and vice versa), and an acoustic value (e.g., an acoustic frequency) that is greater than an acoustic threshold (e.g., an acoustic frequency) can indicate a fault, etc.

In some non-limiting examples, the one or more models can be a mathematical model for the type of the battery (e.g., determined at the block 204) or a physics-based model of the type of battery. In this case, the model can be predictive, in that, various sensor signals (e.g., from different sensors) can be inputted into the model and the model can correspondingly output whether or not a battery fault is present, and if so, a predication of cause of the battery fault (e.g., a short circuit in the battery, high physical stress on the battery, etc.). This can then facilitate how the determined battery fault should be mitigated.

At 206, the process 200 can include a computing device receiving a sensor signal from one or more sensors associated with the battery (e.g., the sensors 110, the sensors 112, etc.). For example, the sensor signals can include a temperature value, a voltage value, a current value, an impedance value, a resistance value, a gas value, a pressure value, an acoustic value (e.g., for a particular acoustic frequency), etc., each of which can be for an individual battery cell of the battery, or for the entire battery. In some cases, this can include the vehicle (or a computing device) transmitting the sensor signal(s) to another computing device for subsequent analysis (e.g., the controller 114 of the headset 104).

At 208, the process 200 can include a computing device determining a presence or an absence of a battery fault of a battery (or an individual battery cell of the battery), based on the sensor signal(s). In some cases, this can include a computing device inputting each sensor signal into a model of the individual battery cell (or the entire battery), which can run on the computing device, the output of which can indicate a presence or an absence of the battery fault for the individual battery cell or the entire battery. In some cases, this can include a computing device comparing each sensor signal to a respective threshold (according to the model, such as the one determined at the block 204) to determine whether or not the corresponding sensor signal exceeds the corresponding threshold. In some cases, if one or more sensor signals exceed their corresponding thresholds (e.g., as defined according to the model for the particular battery type), then a computing device can determine a presence of a battery fault. For example, if a temperature value is greater than a temperature threshold, then a computing device can determine a presence of a battery fault. As another example, if a temperature value is greater than a temperature threshold, and an impedance value is lower than an impedance threshold, then a computing device can determine a presence of a battery fault. In some cases, if one or more sensor signals do not exceed their corresponding thresholds, then a computing device can determine an absence of a battery fault.

In some non-limiting examples, including when one or more sensors are each associated with a respective battery cell of the battery, a computing device can determine a presence (or absence) of a battery fault based on the number of faults for the individual battery cells of the battery. For example, a computing device can determine the presence (or absence) of a fault for each individual battery cell of the battery, as appropriate. Then, a computing device can determine a presence of a battery fault for the entire battery based on the total number of battery faults for individual battery cells being greater than a threshold value (e.g., ten total individual battery cells). Alternatively, if a computing device determines that the total number of battery faults for individual battery cells is lower than the threshold value, then the computing device can determine an absence of a battery fault for the entire battery. In this way, relatively small numbers of individual battery cell faults are not likely to impose risk for the user, but relatively high numbers of individual battery cell faults are likely to impose risk for the user.

In some non-limiting examples, a computing device can determine a type of battery fault, based on the sensor signal(s). For example, a computing device can input the one or more sensor signals into the model, which can output not only the presence (or lack) of a battery fault, but the (likely) type of battery fault (e.g., an anticipated type of battery fault). For example, different sensor signals and combinations of sensor signals can be associated with particular types of battery faults. For example, an internal short circuit for the battery (or individual cell) can be representative of temperature increases and resistance (or impedance) decreases. As another example, thermal runway for the battery (or individual cell) can be representative of temperature increases and gas increases (or pressure increases). In some non-limiting examples, the type of battery fault can be an internal short circuit, thermal runway, abnormal swelling, etc.

At 210, the process 200 can include a computing device, presenting on a display device (e.g., the display device 106 of the headset 108), information indicative of the battery fault (or lack of the battery fault). For example, if a computing device determined an absence of an entire battery fault (e.g., at the block 208), then a computing device can present information indicative of a lack of the battery fault. For example, this can include a computing device presenting an image of a battery that is green, text indicating a lack of a battery fault, etc. As another example, if a computing device determine a presence of the entire battery fault (e.g., at the block 208), then a computing device can present information indicative of a presence of the battery fault, and if applicable, the predicted type of battery fault. For example, this can include a computing device presenting an image of a battery that is red, a battery that is flashing, a battery that has a cross through the battery, text indicating a presence of a battery fault, text indicating the predicted type of battery fault, etc.

At 212, the process 200 can include a computing device, presenting on a display device, information indicative of mitigating the battery fault (e.g., based on the battery type). For example, this information can guide a user in repairing, deactivating, suppressing, or removing the battery (e.g., based on a computing device detecting a battery fault). In some cases, this can include a computing device receiving information indicative of mitigating the battery fault by querying a database (or look-up table) that includes information associated with the battery type, information associated with the type of battery fault, etc. In some cases, this information can be a visual guide (e.g., with illustrations), a user manual, a training video, a user guide, safety protocol, previous safety issues with the type of battery, previous evaluations (e.g., via technicians) of previous battery faults (e.g., of the same type) for the same type of battery, safety guidelines, safety procedures, a location of the individual battery cell with the battery fault, etc. In this way, a user (e.g., wearing the headset) can be presented, via the display, information indicative of the presence (or lack) of a battery fault, and can correspondingly be presented (via the display) with instructions tailored to the battery type, the type of battery fault, etc., to in the best way mitigate the battery fault.

At 214, the process 200 can include mitigating the battery fault, based on the presented information indicative of mitigating the battery fault. For example, the presented information can iteratively guide the user to best mitigate the battery fault, which can include, disconnecting the battery, removing the battery, (safely) storing the removed battery, etc.

Thus, the invention provides a system and a method for detecting, assessing, and displaying a battery fault.

Although the invention has been described in considerable detail with reference to certain non-limiting examples, one skilled in the art will appreciate that the present invention can be practiced by other than the described non-limiting examples, which have been presented for purposes of illustration and not of limitation. Therefore, the scope of the appended claims should not be limited to the description of the non-limiting examples contained herein.

What is claimed is:

1. A system for detecting and assessing a battery fault, the system comprising:
a battery;
a sensor for outputting a sensor signal correlating to a measurement of a chemical, electrical, or physical property of the battery; and
a controller in electrical communication with the sensor and a display device, the controller being configured to execute a program stored in the controller to:
(i) detect and assess a fault in the battery based on the sensor signal, and
(ii) transmit a display signal to the display device such that the display device produces an image indicative of presence or absence of the fault in the battery.

2. The system of claim 1 wherein:
the display device is a headset.

3. The system of claim 1 wherein:
the image is a virtual reality image.

4. The system of claim 1 wherein:
the image is an augmented reality image.

5. The system of claim 1 wherein:
the system includes an image capture device that senses a QR code on the battery or a vehicle including the battery to identify a battery model and retrieve any recorded information from an external database.

6. The system of claim 1 wherein:
the sensor signal is indicative of gas generation, and/or exerted pressure, and/or a short circuit, and/or a type of the battery.

7. The system of claim 1 wherein:
the display device is a headset including the controller.

8. The system of claim 1 wherein:
the display device outputs information to guide a user in repairing, deactivating, suppressing, or removing the battery when a fault is detected in the battery.

9. The system of claim 1 wherein:
the controller is configured to execute a program stored in the controller to detect and assess the fault in the battery based on one or more of the sensor signals and a model of potential fault(s) in a reference battery, wherein the battery is a same type as the reference battery.

10. The system of claim 9 wherein:
the model is used by the controller to determine a display signal to transmit to the display device such that the display device produces an image indicative of a level of safety and potential mitigation strategies for reducing a risk of fire for the battery.

11. The system of claim 9 wherein:
the model includes data on fault(s) encountered in prior accidents for the reference battery.

12. The system of claim 11 wherein:
the data on fault(s) includes data on electric hazards.

13. The system of claim 11 wherein:
the data on fault(s) includes data on gaseous hazards.

14. The system of claim 11 wherein:
the data on fault(s) includes data on thermal hazards.

15. The system of claim 9 wherein:
the model is used by the controller to determine a display signal to transmit to the display device such that the display device produces an image indicative of safety systems and protocols to be used by first responders.

16. The system of claim 9 wherein:
the model is used by the controller to determine a display signal to transmit to the display device such that the display device produces an image indicative of technician evaluations on safety from prior accidents for the reference battery.

17. The system of claim 9 wherein:
the model is used by the controller to determine a display signal to transmit to the display device such that the display device produces an image indicative of guidelines and procedures to minimize exposure to dangerous conditions based on records of prior accidents and the model prediction for the reference battery.

18. The system of claim 9 wherein:
the model is used by the controller to determine a display signal to transmit to the display device such that the display device produces an image indicative of prediction of evolution of the fault(s).

19. The system of claim 9 wherein:
the model is used by the controller to determine a display signal to transmit to the display device such that the display device produces an image indicative of an internal state of the battery.

20. The system of claim 9 wherein:
the model is used by the controller to determine a display signal to transmit to the display device such that the display device produces an image indicative of failed cell location in the battery and a prediction of fault and battery state of health evolution with time.

21. The system of claim 9 wherein:
the model is used by the controller to determine a display signal to transmit to the display device such that the display device produces an image indicative of a threshold of response safety levels for a user in case of battery fault detection.

22. The system of claim 1 wherein:
the display device outputs information to guide a user in a signal excitation for creating a signal response to be sensed by the sensor for outputting the sensor signal to the controller to detect and assess the fault in the battery.

23. The system of claim 22 wherein:
the signal excitation is selected from electrochemical impedance spectroscopy signals, acoustic signals, infra-red signals, and thermography signals.

24. The system of claim 1 wherein:
the controller includes an image capture device that senses a visual aspect of the battery or a vehicle including the battery to identify a battery model and retrieve any recorded information from an external database.

25. A method for detecting and assessing a battery fault, the method comprising:
(a) receiving in a controller a sensor signal correlating to a measurement of a chemical, electrical, or physical property of a battery, the controller being in electrical communication with a display device;
(b) detecting and assessing in the controller a fault in the battery based on the sensor signal; and
(c) transmitting a display signal from the controller to the display device such that the display device produces an image indicative of presence or absence of a fault in the battery.

26. The method of claim 25 wherein:
the display device is a headset.

27. The method of claim 25 wherein:
the image is a virtual reality image.

28. The method of claim 25 wherein:
the image is an augmented reality image.

29. The method of claim 25 further comprising:
sensing a QR code on the battery or a vehicle with an image capture device of the controller to identify a battery model and retrieve any recorded information from an external database.

30. The method of claim 25 further comprising:
sensing a visual aspect of the battery or a vehicle with an image capture device of the controller to identify a battery model and retrieve any recorded information from an external database.

31. The method of claim 25 wherein:
the sensor signal is indicative of gas generation, and/or exerted pressure, and/or a short circuit, and/or a type of the battery.

32. The method of claim 25 wherein:
the display device outputs information to guide a user in repairing, deactivating, suppressing, or removing the battery when a fault is detected in the battery.

33. The method of claim 25 wherein:
the display device outputs information to a user with projections of any internal evolving fault(s) along with the prediction for the evolution of the battery fault and the guiding towards safe interventions.

34. The method of claim 25 wherein:
the controller is configured to execute a program stored in the controller to detect and assess the fault in the battery based on the sensor signal and a model of potential fault(s) in a reference battery, wherein the battery is a same type as the reference battery.

35. The method of claim 34 wherein:
the model is used by the controller to determine a display signal to transmit to the display device such that the display device produces an image indicative of a level of safety and potential mitigation strategies for reducing a risk of fire for the battery.

36. The method of claim 34 wherein:
the model includes data on fault(s) encountered in prior accidents for the reference battery.

37. The method of claim 36 wherein:
the data on fault(s) includes data on electric hazards.

38. The method of claim 36 wherein:
the data on fault(s) includes data on gaseous hazards.

39. The method of claim 36 wherein:
the data on fault(s) includes data on thermal hazards.

40. The method of claim 34 wherein:
the model is used by the controller to determine a display signal to transmit to the display device such that the display device produces an image indicative of safety systems and protocols to be used by first responders.

41. The method of claim 34 wherein:
the model is used by the controller to determine a display signal to transmit to the display device such that the display device produces an image indicative of technician evaluations on safety from prior accidents for the reference battery.

42. The method of claim 34 wherein:
the model is used by the controller to determine a display signal to transmit to the display device such that the display device produces an image indicative of guidelines and procedures to minimize exposure to dangerous conditions based on prior accidents for the reference battery.

43. The method of claim 34 wherein:
the model is used by the controller to determine a display signal to transmit to the display device such that the display device produces an image indicative of prediction of evolution of the fault(s).

44. The method of claim 34 wherein:
the model is used by the controller to determine a display signal to transmit to the display device such that the display device produces an image indicative of an internal state of the battery.

45. The method of claim 34 wherein:
the model is used by the controller to determine a display signal to transmit to the display device such that the display device produces an image indicative of failed cell location in the battery and a prediction of fault and battery state of health evolution with time.

46. The method of claim 34 wherein:
the model is used by the controller to determine a display signal to transmit to the display device such that the display device produces an image indicative of a threshold of response safety levels for a user in case of battery fault detection.

47. The method of claim 25 wherein:
the display device outputs information to guide a user in a signal excitation for creating a signal response to be sensed by the sensor for outputting the sensor signal to the controller to detect and assess the fault in the battery.

48. The method of claim 47 wherein:
the signal excitation is selected from electrochemical impedance spectroscopy signals, acoustic signals, infra-red signals, and thermography signals.

49. A training system comprising:
a display device; and
a controller in electrical communication with the display device, the controller being configured to execute a program stored in the controller to:
(i) transmit a display signal to the display device to produce on the display device an image of a battery having a fault, and a user guide for repairing, deactivating, suppressing, or removing the battery fault.

50. The system of claim 49 wherein:
the display device is a headset.

51. The system of claim 49 wherein:
the image is a virtual reality image.

52. The system of claim 49 wherein:
the image is an augmented reality image.

53. The system of claim 49 wherein:
the controller includes an image capture device that senses a QR code on a battery or a vehicle including the battery to identify a battery model and retrieve any recorded information from an external database.

54. The system of claim 49 wherein:
the fault is gas generation and/or a short circuit.

55. The system of claim 49 wherein:
the display device is a headset including the controller.

56. A method for training a user on repairing, deactivating, suppressing, or removing a battery fault, the method comprising:
transmitting a display signal from a controller to a display device to produce on the display device an image of a battery having a fault, and a user guide for repairing, deactivating, suppressing, or removing the battery fault.

57. The method of claim 56 wherein:
the display device is a headset.

58. The method of claim 56 wherein:
the image is a virtual reality image.

59. The method of claim 56 wherein:
the image is an augmented reality image.

60. The method of claim 56 further comprising:
sensing a QR code on a battery or a vehicle including the battery with an image capture device of the controller to identify a battery model and retrieve any recorded information from an external database.

61. The method of claim 56 further comprising:
sensing a visual aspect of the battery or a vehicle with an image capture device of the controller to identify a battery model and retrieve any recorded information from an external database.

62. The method of claim 56 wherein:
the fault is gas generation and/or a short circuit.

63. The method of claim 56 wherein:
the display device is a headset including the controller.
